(19) United States
(12) Patent Application Publication
(10) Pub. No.: US 2026/0348891 A1
(43) Pub. Date: Nov. 5, 2026

(54) Nuclear Magnetic Resonance Method For Determining Spontaneous Imbibition In Rock Samples

(71) Applicant: Chevron U.S.A. Inc., San Ramon, CA (US)

(72) Inventors: Boqin Sun, Houston, TX (US); Zheng Yang, Katy, TX (US); Robert Keays Mallan, Houston, TX (US)

(21) Appl. No.: 19/199,064

(22) Filed: May 5, 2025

(51) Int. Cl. G01N 24/08; G01N 15/08; G01R 33/50

(52) U.S. Cl. CPC G01N 24/081; G01N 15/0806; G01R 33/50

(57) ABSTRACT

A system and method for generating an imbibition model for a rock core sample uses nuclear magnetic resonance to determine a porosity characteristic indicating a production mechanism for the rock core sample. A reservoir environment is simulated by first saturating the rock core sample with a liquid hydrocarbon. The hydrocarbon-saturated rock core sample is subsequently placed in a vessel of deuterated brine. The rock core sample is periodically removed from the deuterated brine to measure by NMR the change in the saturation of the rock core sample, which indicates a porosity of the rock core sample. The collected porosity data is fit to a dual rate imbibition model reflecting pore size distributions and rock heterogeneity. The dual rate model can be used for managing water injection into a rock formation represented by the rock core sample.

### TECHNICAL FIELD

Embodiments of the technology relate generally to using a nuclear magnetic resonance (NMR) method for determining a model of spontaneous water imbibition in rock samples.

### BACKGROUND

A common way to improve oil or gas extraction from a hydrocarbon reservoir is by injecting water, via an injection well, into a rock formation in the hydrocarbon reservoir. The injection of the water into the rock formation assists with maintaining pressure in the reservoir and pushing the oil or gas toward the production wells. When water is injected into a hydrocarbon well, the rock formation commonly exhibits spontaneous water imbibition. Spontaneous imbibition is the adsorption, due to capillary forces, of the water into the pores of the rock formation.

Different types of rock exhibit varying degrees of spontaneous imbibition. With a high degree of spontaneous imbibition, the rock formation can adsorb more water, thereby promoting greater discharge of hydrocarbons from the pores of the rock formation. In contrast, with a low degree of spontaneous imbibition, excess water is not as readily adsorbed into the rock formation and, instead, blocks the flow of hydrocarbons from the pores of the rock formation. Therefore, an accurate understanding of spontaneous imbibition for a particular rock formation is useful for optimizing water injection and the production of hydrocarbons. Such an understanding is particularly useful for rock formations that are significantly fractured because spontaneous imbibition is a significant factor affecting the production of hydrocarbons.

The degree to which a rock formation will exhibit spontaneous imbibition can be challenging to determine accurately as it depends upon the type of rock as well as environmental factors such as the temperature and pressure within the rock formation. Previously, mathematical models have been developed in an attempt to understand spontaneous water imbibition driven by capillary forces in rock formations. However, as described further below, previous models of this phenomenon are prone to inaccuracy due to oversimplifications or imprecision in measurement methods. Therefore, a more accurate mathematical model for describing spontaneous water imbibition would be useful.

### SUMMARY

The present disclosure is directed to systems and methods for determining a spontaneous imbibition model for a rock formation and using the model for injecting a fluid into the rock formation.

In a first embodiment, a method for generating an imbibition model may comprise: (a) saturating a rock core sample from a rock formation with a liquid hydrocarbon to simulate a reservoir environment within the rock formation; (b) performing nuclear magnetic resonance (NMR) spectroscopy on the rock core sample saturated with the liquid hydrocarbon and obtaining a base line NMR measurement; (c) immersing the rock core sample in deuterated brine within a vessel; (d) applying a temperature and a pressure to the rock core sample within the vessel to simulate conditions of the reservoir environment; (e) obtaining multiple imbibed NMR measurements over a predetermined time by periodically removing the rock core sample from the vessel and performing the NMR spectroscopy on the rock core sample; (f) calculating inversions of the base line NMR measurement and the multiple imbibed NMR measurements to determine a porosity characteristic based upon a change in hydrocarbon saturation in the rock core sample during the predetermined time; and (g) fitting the porosity characteristic of the base line NMR measurements and the multiple imbibed NMR measurements to an imbibition model of hydrocarbon saturation for the rock core sample.

The method of the foregoing first embodiment may also include one or more of the following aspects. The imbibition model may comprise a first imbibition rate and a second imbibition rate, wherein the first imbibition rate corresponds to a first type of pores in the rock core sample and the second imbibition rate corresponds to a second type of pores in the rock core sample that are larger than the first type of pores. In the foregoing method, the base line NMR measurement and the multiple imbibed NMR measurements comprise one of T2 measurements, T1-T2 measurements, and DT2 measurements.

In the foregoing method of the first embodiment, the NMR spectroscopy may employ an echo train that produces a time-domain echo decay curve, wherein the echo train comprises a sequence of echo pulses spaced apart by an echo time. Furthermore, calculating inversions of the base line NMR measurement and the multiple imbibed NMR measurements may comprise transforming the time-domain echo decay curves into at least one of a one-dimensional distribution and a two-dimensional distribution. Additionally, in the foregoing method the temperature may be a selected temperature between 50 degrees F to 200 degrees F and the pressure may be a selected pressure between 14 psi and 2000 psi.

In a second embodiment, a method for applying a dual rate imbibition model may comprise: (a) generating the dual rate imbibition model characterizing imbibition for a rock core sample, wherein the dual rate imbibition model is generated from multiple nuclear magnetic resonance (NMR) measurements of the rock core sample, wherein the dual rate imbibition model comprises a fast imbibition rate and a slow imbibition rate; and (b) adjusting, based on the fast imbibition rate and the slow imbibition rate, a rate at which a fluid is pumped during a time period into a rock formation represented by the rock core sample.

The method of the foregoing second embodiment may also include one or more of the following aspects. The rate at which the fluid is pumped into the formation may be greater during an earlier portion of the time period than during a later portion of the time period. The dual rate model may correspond to a type of rock of the formation. The first imbibition rate may correspond to a first type of pores in the rock core sample and the second imbibition rate may correspond to a second type of pores in the rock core sample that are larger than the first type of pores.

The foregoing second embodiment may further comprise generating the dual rate model by a method that may comprise: (a) saturating the rock core sample with a liquid hydrocarbon to simulate a reservoir environment within the rock formation; (b) performing NMR spectroscopy on the rock core sample saturated with the liquid hydrocarbon and obtaining a base line NMR measurement; (c) immersing the rock core sample in deuterated brine within a vessel; (d) applying a temperature and a pressure to the rock core sample within the vessel to simulate conditions of the reservoir environment; (e) obtaining multiple imbibed NMR measurements over a predetermined time by periodically removing the rock core sample from the vessel and performing the NMR spectroscopy on the rock core sample; (f) calculating inversions of the base line NMR measurement and the multiple imbibed NMR measurements to determine a porosity characteristic based upon a change in hydrocarbon saturation in the rock core sample during the predetermined time; and (g) fitting the porosity characteristic of the base line NMR measurements and the multiple imbibed NMR measurements to the dual rate imbibition model for the rock core sample. In generating the dual rate model, the base line NMR measurement and the multiple imbibed NMR measurements may comprise one of T2 measurements, T1-T2 measurements, and DT2 measurements. The NMR spectroscopy may employ an echo train that produces a time-domain echo decay curve, wherein the echo train comprises a sequence of echo pulses spaced apart by an echo time. Calculating inversions of the base line NMR measurement and the multiple imbibed NMR measurements may comprise transforming the time-domain echo decay curves into at least one of a one-dimensional distribution and a two-dimensional distribution. Additionally, in the foregoing method the temperature may be a selected temperature between 50 degrees F to 200 degrees F and the pressure may be a selected pressure between 14 psi and 2000 psi.

In a third embodiment, a system may comprise: (a) a vessel containing deuterated water, the vessel configured to immerse a rock core sample in the deuterated water and apply a temperature and a pressure to the rock core sample to simulate a reservoir environment; (b) a nuclear magnetic resonance (NMR) system, the NMR system configured to: (i) obtain, by NMR spectroscopy, base line NMR measurements from the rock core sample when it is saturated with a hydrocarbon liquid and before it is immersed in the vessel; and (ii) obtain multiple imbibed NMR measurements over a predetermined time by periodically removing the rock core sample from the vessel and performing NMR spectroscopy on the rock core sample; and (c) a computing system configured to: (i) calculate inversions of the base line NMR measurements and the multiple imbibed NMR measurements to determine a porosity characteristic based upon a change in hydrocarbon saturation in the rock core sample during the predetermined time; and (ii) fit the porosity characteristic of the base line NMR measurements and the multiple imbibed NMR measurements to an imbibition model of hydrocarbon saturation for the rock core sample.

The system of the foregoing third embodiment may include one or more of the following aspects. The model may comprise a first imbibition rate and a second imbibition rate. The base line NMR measurement and the multiple imbibed NMR measurements may comprise one of T2 measurements, T1-T2 measurements, and DT2 measurements. The NMR spectroscopy may employ an echo train that produces a time-domain echo decay curve, wherein the echo train comprises a sequence of echo pulses spaced apart by an echo time.

The foregoing embodiments are non-limiting examples and other aspects and embodiments will be described herein. The foregoing summary is provided to introduce various concepts in a simplified form that are further described below in the detailed description. This summary is not intended to identify required or essential features of the claimed subject matter nor is the summary intended to limit the scope of the claimed subject matter.

### BRIEF DESCRIPTION OF THE DRAWINGS

The accompanying drawings illustrate only example embodiments of systems and methods for determining a spontaneous imbibition model for a rock formation and using the model for injecting a fluid into the rock formation. Therefore, the examples provided are not to be considered limiting of the scope of this disclosure. The principles illustrated in the example embodiments of the drawings can be applied to alternate methods and apparatus. Additionally, the elements and features shown in the drawings are not necessarily to scale, emphasis instead being placed upon clearly illustrating the principles of the example embodiments. Certain dimensions or positions may be exaggerated to help visually convey such principles. In the drawings, the same reference numerals used in different embodiments designate like or corresponding, but not necessarily identical, elements.

FIG. 1 illustrates an example of a method for measuring spontaneous imbibition in a rock sample in accordance with the prior art.

FIG. 2 illustrates an example system for immersing in deuterated brine a hydrocarbon saturated rock sample in accordance with an example embodiment of the disclosure.

FIG. 3 illustrates an NMR system and computing system in accordance with an example embodiment of the disclosure.

FIG. 4 is a flowchart illustrating an example method for generating an imbibition model in accordance with an example embodiment of the disclosure.

FIG. 5 is a flowchart illustrating an example method for applying an imbibition model to pumping a liquid into a rock formation in accordance with an example embodiment of the disclosure.

FIG. 6 is a plot of NMR data illustrating the effect of imbibition in accordance with an example embodiment of the disclosure.

FIG. 7 is a plot of porosity data relative to a conventional BCLW model of imbibition.

FIG. 8 is a plot of porosity data relative to a dual rate model of imbibition in accordance with an example embodiment of the disclosure.

FIG. 9 illustrates parameter values of a dual rate model for various rock samples in accordance with an example embodiment of the disclosure.

FIG. 10 illustrates a CPMG pulse sequence for NMR spectroscopy to measure the effect of imbibition on a rock sample in accordance with an example embodiment of the disclosure.

FIG. 11 illustrates a T1 pulse sequence for T1-T2 two-dimensional NMR spectroscopy to measure the effect of imbibition on a rock sample in accordance with an example embodiment of the disclosure.

### DETAILED DESCRIPTION OF EXAMPLE EMBODIMENTS

The example embodiments discussed herein are directed to systems and methods for determining spontaneous imbibition of water in a rock formation, such as a rock formation in a hydrocarbon reservoir. As explained above, existing approaches to understanding spontaneous imbibition in rock formations are limited and prone to inaccuracy. An improved approach to determining spontaneous water imbibition in a rock formation would be useful in managing the injection of water or injection fluid into a rock formation and, thereby, improving the production of hydrocarbons from the formation.

In the following paragraphs, particular embodiments will be described in further detail by way of example with reference to the drawings. In the description, well-known components, methods, and/or processing techniques are omitted or briefly described. Furthermore, reference to various feature(s) of the embodiments is not to suggest that all embodiments must include the referenced feature(s).

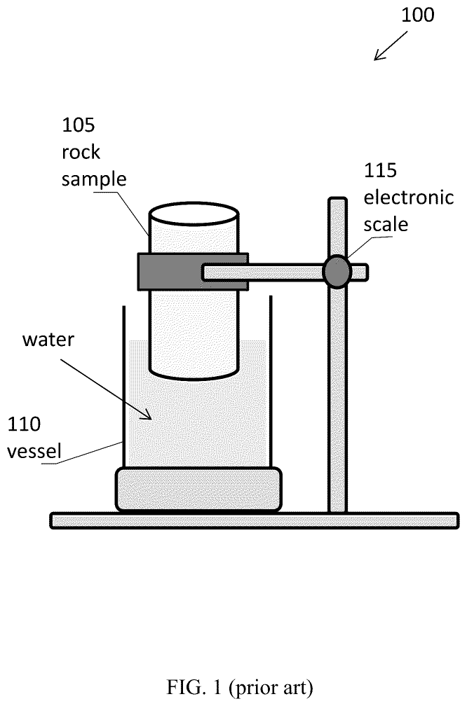

Referring to FIG. 1, a system 100 is illustrated for determining spontaneous imbibition in accordance with the prior art. The prior art approach illustrated in FIG. 1 involves suspending a rock sample 105 in a vessel 110 containing water. As capillary forces cause water to be adsorbed into the pores of the rock sample 105, the weight of the rock sample increases. An electronic scale 115 measures the change in the weight of the rock sample to determine the amount of spontaneous water imbibition.

The prior art approach illustrated in FIG. 1 is inadequate for accurately assessing spontaneous water imbibition as it would occur in a rock formation. First, with the system 100 of FIG. 1 it is difficult to simulate the elevated pressure and temperature conditions that would be typical of a rock formation in a hydrocarbon well. Second, the measurement of the weight change in the rock sample is susceptible to inaccuracy due to evaporation of the water from the rock sample. Third, it is not possible to simulate the original condition of the rock sample in the rock formation wherein it would contain hydrocarbon gas and/or liquid. Lastly, the simple measurement of the weight of the rock sample does not provide useful insight into the heterogeneity and varying pore sizes encountered within the rock sample.

The prior art also includes approaches to develop a mathematical model of spontaneous imbibition in a rock sample. As one example, Lucas and Washburn analyzed the imbibition behavior of an ideal cylindrical tube and derived mathematical expressions for imbibition height over time. More recently, a modified version of the mathematical expressions from Lucas and Washburn is an imbibition model known as the Bell-Cameron-Lucas-Washburn (BCLW) model. The BCLW model is described with the following equation:

$${z}^{2} ( t ) = \frac{{γ}_{l v} R cos θ}{2 η} t + {z}_{0}^{2} \qquad ( equation l )$$

wherein z is the average height of wetting fluid in capillary tubes; γ_{Iv} is the liquid-vapor surface tension; Θ is the liquid-vapor-substrate contact angle; η is the viscosity of the liquid; R is the radius of the cylindrical channel; t is elapsed time; z is penetration depth as a function of time t; and z₀ represents start-up effects before equation 1 dominates the imbibition.

In another example, L. L. Handy studied the imbibition process in real porous media and the Handy model was proposed to describe a piston-like imbibition profile.

A shortcoming of the prior approaches to modeling imbibition is that they rely upon a simplification in which capillaries have a cylindrical shape. However, the pores in rock formations typically have irregular shapes that do not closely resemble a cylindrical shape. Moreover, the pore sizes typically vary in size with a mix of larger pores and smaller pores exhibiting different imbibition rates that depend upon their size. Therefore, developing a mathematical model that more accurately reflects the heterogeneity of the rock formations encountered in hydrocarbon reservoirs would be more useful.

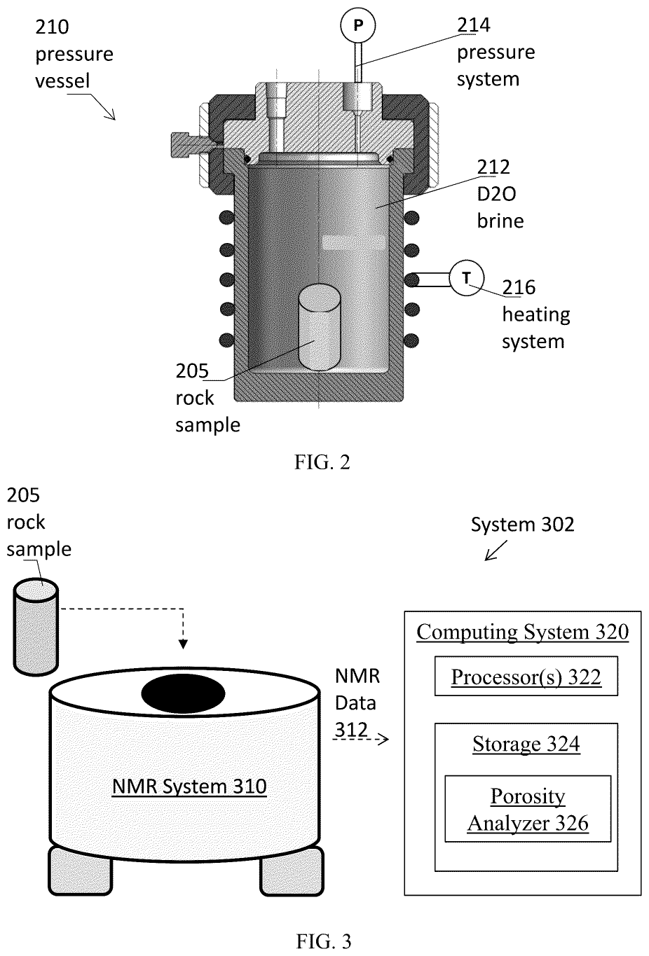

The present disclosure provides a model and a method for developing the model that more accurately characterizes the spontaneous imbibition phenomenon for rock formations. Referring first to FIGS. 2, 3 and 4, an example method and example systems are described for generating an imbibition model. Beginning with operation 410, one or more rock core samples are obtained from a rock formation in a hydrocarbon reservoir. While the figures refer to a single rock core sample for simplicity, multiple rock core samples can be tested, either simultaneously or sequentially, in a manner similar to that illustrated in FIGS. 2-4 to obtain a more comprehensive set of data on which to base the imbibition model. As further described in operation 410, the rock core sample is saturated with a liquid hydrocarbon to simulate the reservoir environment in which the rock formation is located. The rock core sample may be saturated in the hydrocarbon by submerging the rock core sample in a vessel containing the hydrocarbon. Additionally, the vessel in which the rock core sample is saturated with the hydrocarbon may be pressurized and/or heated to simulate the environment of the hydrocarbon reservoir from which the rock core sample was retrieved. The saturation of the rock core sample with liquid hydrocarbon and the application of pressure and/or heat to the rock core sample may be performed using the pressure vessel 210 of FIG. 2, which is described further below, or using a similar vessel.

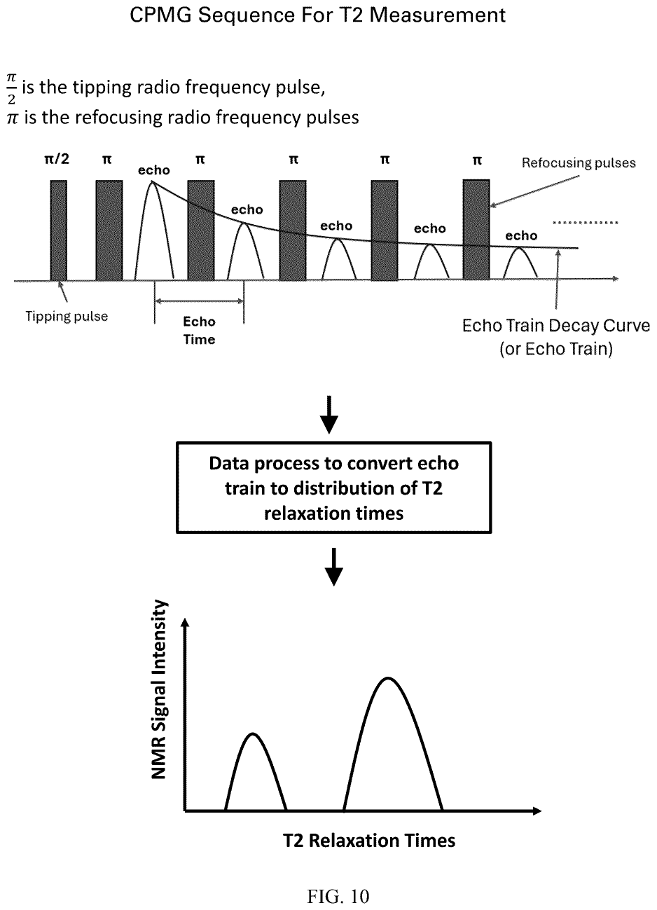

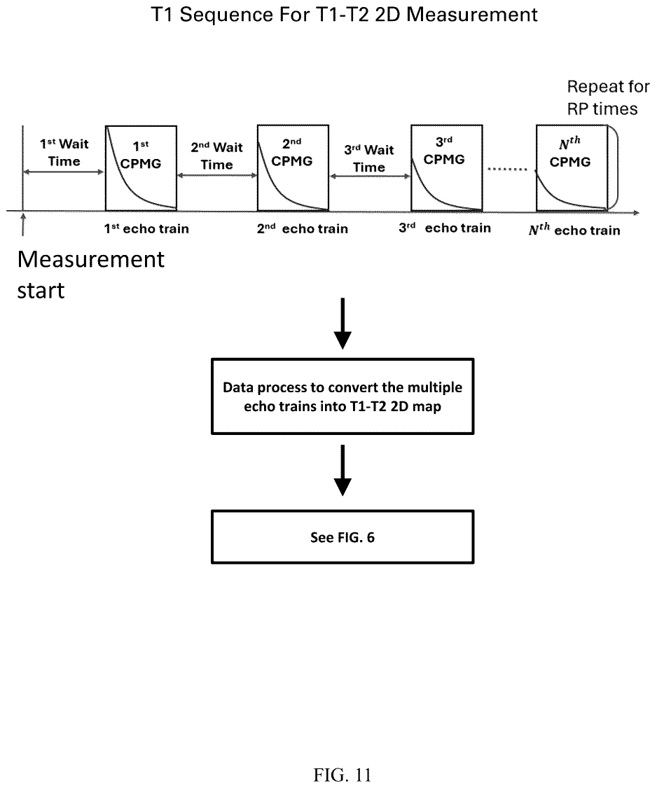

Referring to operation 420, after completing the saturation with the hydrocarbon, the rock core sample 205 may be placed in an NMR system 310 and analyzed with T2 or T1-T2 NMR spectroscopy to obtain a base line NMR measurement, referred to as NMR data 312 in FIG. 3. In the case of T2 NMR spectroscopy, a CPMG (Carr-Purcell-Meiboom-Gill) sequence of pulses such as that shown in FIG. 10 is used. Alternatively, in the case of T1-T2 NMR spectroscopy, a sequence of CPMG echo trains such as that shown in FIG. 11 is used. In other embodiments, other NMR spectroscopy techniques, such as DT2, may be used to analyze the sample. The base line NMR measurement will be used for comparison to the imbibed NMR measurements described below.

Referring to operation 430, the rock core sample 205 is placed in pressure vessel 210. To simulate conditions in the rock formation when water or injection fluid is injected into the rock formation, the vessel 210 is filled with deuterated brine 212. Deuterated brine 212 is selected because deuterium is undetectable by low field NMR spectroscopy. Therefore, as the deuterated brine flows into the pores of the rock core sample, it will appear invisible in the NMR data and provide a contrast to the hydrocarbon fluid in the pores of the rock core sample. As further described in operation 430, reservoir conditions can be further simulated by adjusting the pressure and/or temperature within the pressure vessel 210. A pressure system 214 can be used to increase the pressure within the pressure vessel 210 to a pressure that would be typical for the rock formation in a hydrocarbon reservoir. As an example, the pressure may be increased to a range of 1000 to 2000 psi. A heating system 216 can be used to increase the temperature within the pressure vessel 210 to a temperature that would be typical for the rock formation in a hydrocarbon reservoir. As an example, the temperature may be increased to within a range of 100 to 200 degrees F. Alternatively, the rock core sample 205 may be held at room temperature (e.g., 50 to 100 degrees F) and atmospheric pressure (e.g., 14 psi) when submerged in the pressure vessel 210.

Referring to operation 440, the rock core sample 205 is removed from the pressure vessel 210 after a specified time to perform NMR spectroscopy on the sample. At the specified time, the sample may have undergone spontaneous imbibition wherein the deuterated brine may have been adsorbed into a portion of the pores of the rock core sample 205. The NMR spectroscopy will produce imbibed NMR data indicating the extent of the decrease in hydrocarbon saturation in the rock core sample 205 as it begins to imbibe the deuterated brine.

As referenced above, there are various NMR spectroscopy techniques that may be used to analyze the sample and in certain embodiments multiple techniques may be used. FIG. 10 illustrates the case of T2 NMR spectroscopy in which a CPMG (Carr-Purcell-Meiboom-Gill) sequence of echo pulses is used to provide an echo train. The echo pulses are spaced from each other by an echo time and produce an echo decay curve. The signals from the echo train are converted into a distribution of T2 relaxation times that provide an indication of porosity for the rock core sample. Alternatively, FIG. 11 illustrates the case of T1-T2 NMR spectroscopy in which a sequence of CPMG echo trains is used. Each of the echo trains in FIG. 11 are spaced apart by a wait time. The signals from the multiple echo trains of FIG. 11 are converted into a T1-T2 two-dimensional graphical distribution.

As indicated in operation 450, operations 430 and 440 can be repeated any number of times to obtain imbibed NRM data over time. Over time, as spontaneous imbibition causes more of the deuterated brine to displace hydrocarbon in the pores of the rock core sample due to capillary force, the NMR signal will decrease because the deuterated brine is not detectable by the low field NMR signal. In other words, the NMR apparent porosity of the rock core sample 205 will decrease over time as the rock core sample 205 is submerged in the deuterated brine. This variation in the NMR apparent porosity over time can be used to calculate an imbibition rate for the rock core sample 205.

In operation 460, inversion calculations can be performed on the base line NMR data and the imbibed NMR data to generate graphical representations of the spontaneous imbibition. As illustrated in FIG. 3, a computing system 320 can receive the base line and imbibed NMR data. The computing system 320 can include typical components of a computing system, such as one or more processors 322, a memory, input/output interfaces, a computer-readable storage 324, and a porosity analyzer 326 comprising computer-executable instructions for performing the computing operations described herein. The computing components illustrated in FIG. 3 are merely illustrative examples and in alternate embodiments the computing components can be modified or distributed in a different manner. While the porosity analyzer 326 is illustrated in FIG. 3 as a software module stored on storage device 324 of computing system 320, in alternate embodiments the porosity analyzer can be implemented as one or more services available on remote computing devices, such as the cloud, which services can be accessed to analyze the NMR data.

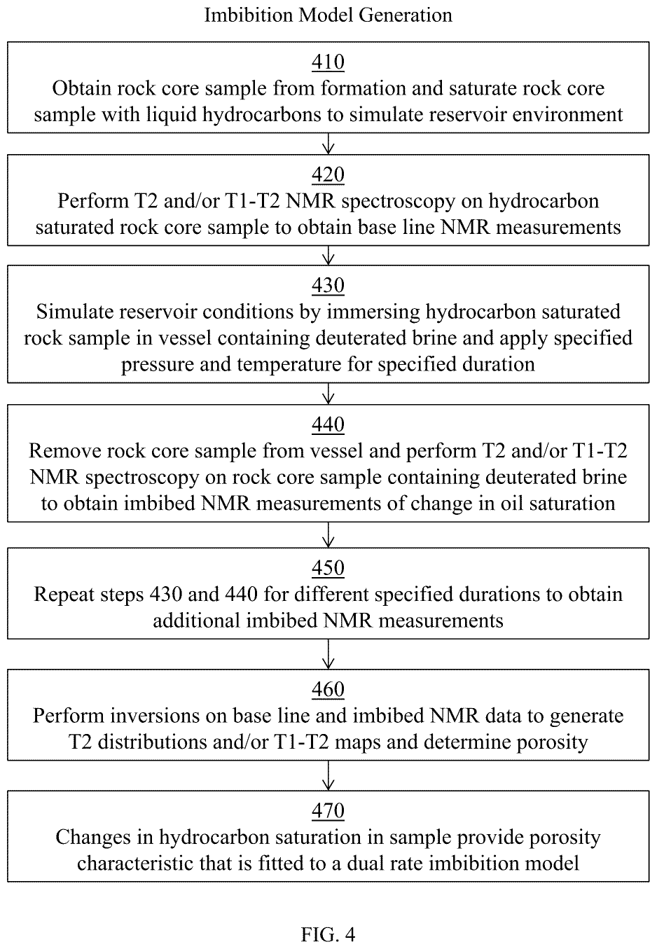

The porosity analyzer 326 can perform inversion calculations on the NMR data and generate graphical representations of the NMR data as illustrated in FIG. 6. The inversion calculations can include one-dimensional and two-dimensional Laplace algorithms to transfer the time-domain echo decay curves acquired from the echo trains illustrated in FIG. 10 and/or FIG. 11 into a T2 distribution and/or a T1-T2 distribution. The data illustrated in FIG. 6 was generated by testing rock core samples using the method of FIG. 4. The testing was performed at a temperature 200 degrees F over a period of 316 hours.

The distributions shown in FIG. 6 illustrate that the intensity of the oil peaks in the NMR data decrease over time due to imbibition of the deuterated brine into the rock core sample. In other words, the decreasing peaks have a longer T1-T2 relaxation time indicating the presence of the deuterated water in the pores. The smaller peak towards the left side of the distribution in FIG. 6 corresponds with pores of smaller size, whereas the larger peak towards the right side of the distribution corresponds with larger pores. Prior art spontaneous imbibition models are limited in that they are based on average behavior of the porous media and do not address rock heterogeneity and pore size distribution. In contrast, as illustrated by the different peaks in FIG. 6, the method of the present embodiment provides not only porosity for the rock core sample, but also detailed information about the pore size distribution and the rates of spontaneous imbibition in the different types of pores. The volume of each peak in FIG. 6 provides the pore volume for the pores of a particular size. Thus, the distributions in FIG. 6 provide a porosity characteristic for the rock core sample. The porosity characteristic may be referred to as an apparent porosity of the rock core sample. Alternatively, the porosity characteristic also may be a pore volume calculated from the pore volume as a fraction of the entire volume of the sample.

Operations 410 through 460 of FIG. 4 may be performed on multiple rock core samples to gather additional porosity characteristic data that may be used in generating a model of the spontaneous imbibition. Referring now to operation 470, the method of the present embodiment provides a more accurate spontaneous imbibition model that addresses rock heterogeneity and pore size distribution. The decrease in hydrocarbon saturation of the rock core sample over time as indicated by the NMR data, and as illustrated in FIG. 6, provides a porosity characteristic for the rock core sample that can be fitted to an imbibition model with model parameters.

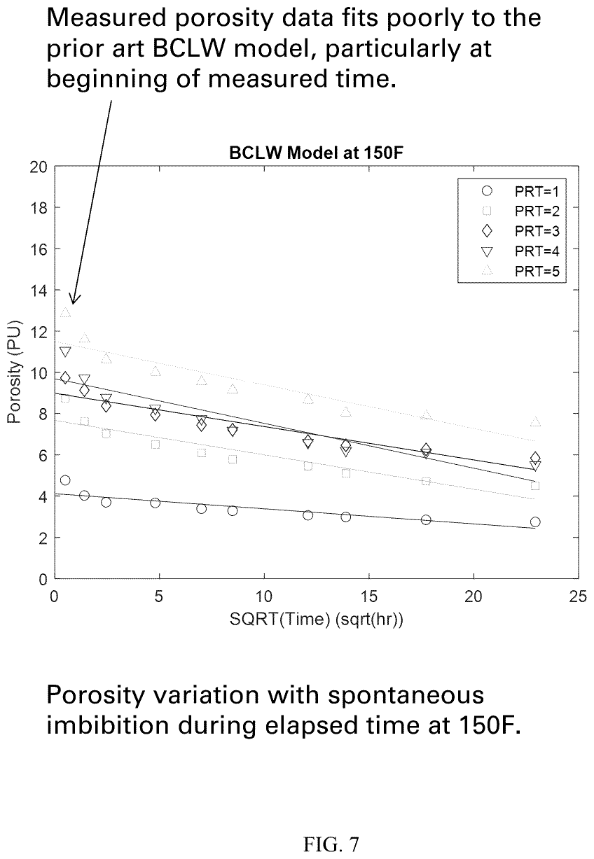

FIG. 7 illustrates an attempt to fit porosity characteristic data gathered using the example method of FIG. 4 to a conventional BCLW model of imbibition. However, as illustrated in FIG. 7, the porosity characteristic data fits poorly to the BCLW model, particularly for the data towards the beginning of the measurements at the left side of the data plot in FIG. 7.

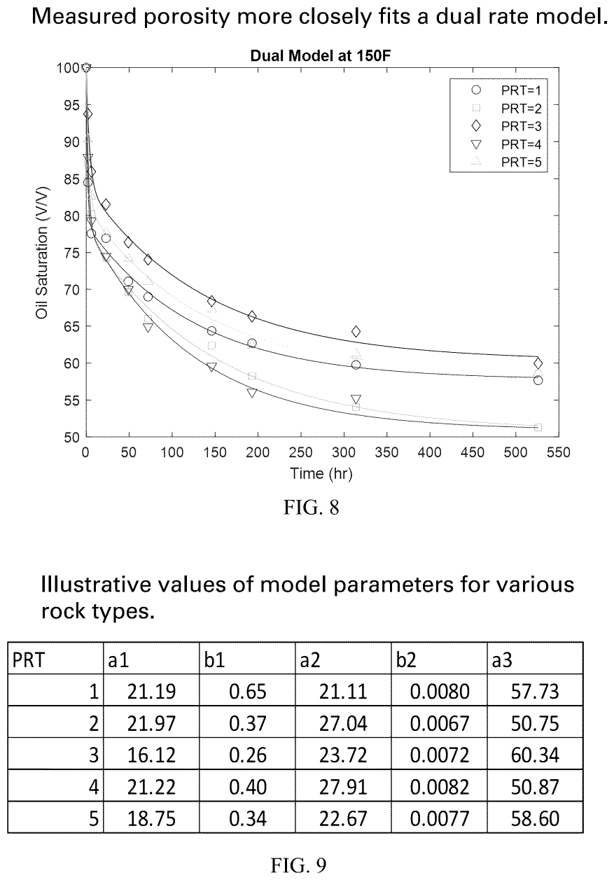

In contrast, as illustrated in FIG. 8, porosity characteristic data gathered using the example method of FIG. 4 can be accurately fitted to a dual rate model, such as the following:

Sₒ=a₁ exp(−b₁t)+a₂ exp(−b₂t)+a₃ (equation 2)

In equation 2, Sₒ is oil saturation, a₁ is the amount of saturation that undergoes fast spontaneous imbibition at a rate of b₁, a₂ is the amount of saturation that undergoes slow spontaneous imbibition at a rate of b₂. The coefficient a₃ represents the final oil saturation reached by the spontaneous imbibition production mechanism. FIG. 9 shows values of the model parameters for various rock types determined using the example method of FIG. 4. FIG. 8 illustrates that the porosity characteristic data gathered using the method of FIG. 4 more accurately fits the dual rate model of equation 2. The model parameter values in FIG. 9 and the data plot in FIG. 6 indicate that the slower spontaneous imbibition rate of the larger pores is approximately 100 times slower than the faster spontaneous imbibition rate of the smaller pores. The data plot in FIG. 6 shows that the faster spontaneous imbibition rate of the smaller pores averages 0.5%/hour, whereas the slower spontaneous imbibition rate of the larger pores averages 0.007%/hour. Additionally, the a3 coefficient of the values in FIG. 9 indicates the final oil saturation for the various rock types is approximately 50% to 60%.

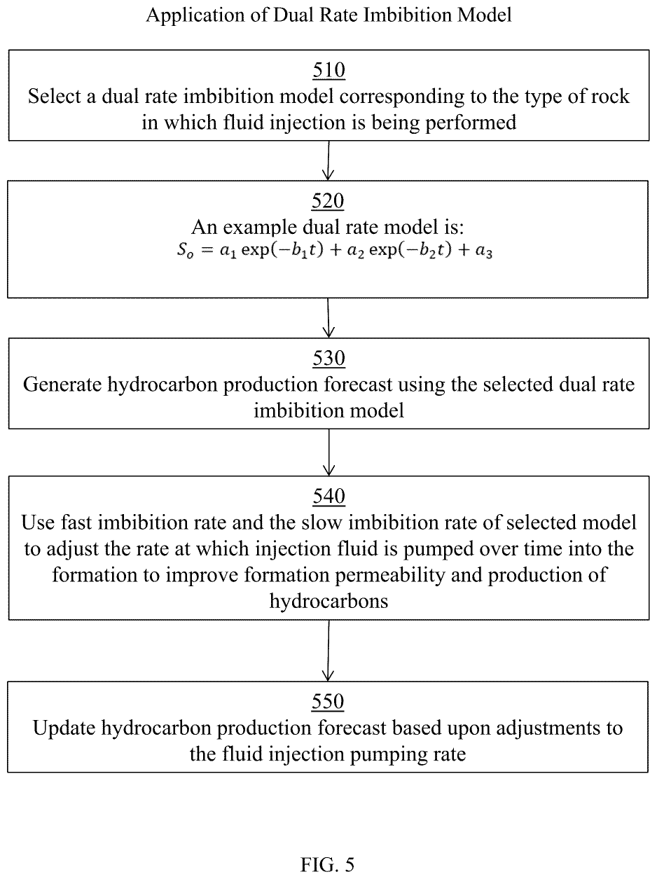

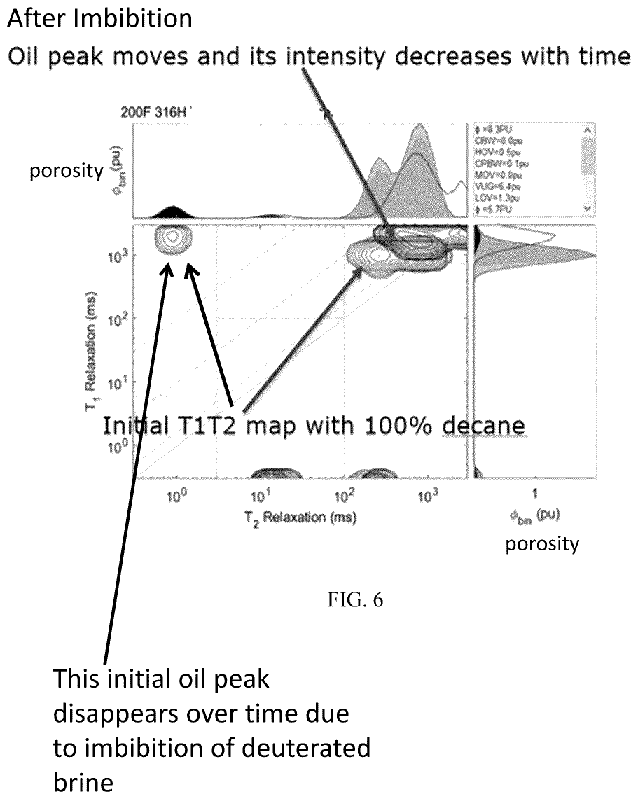

Referring to FIG. 5, an example method is illustrated for using the spontaneous imbibition model generated by the method of FIG. 4. In operation 510, a well operator can select a dual rate imbibition model corresponding to a type of rock formation in which fluid injection is being performed. As indicated in operation 520, a dual rate model such as equation 2 generated by the method of FIG. 4 can provide a more accurate model of spontaneous imbibition associated with injecting a fluid (e.g., water) into the rock formation. As described previously, a dual rate spontaneous imbibition model can be used to assess the adsorption of injection fluid into the pores of the rock formation and the resulting displacement of a hydrocarbon from the pores. Accordingly, in operation 530, the well operator may generate a hydrocarbon production forecast for the rock formation using the selected dual rate imbibition model. In operation 540, the well operator may use the dual rate imbibition model to adjust the rate at which the injection fluid is pumped into the rock formation. The dual rate imbibition model provides insight into the rate at which the injection fluid will be adsorbed by both large and small pores in the rock formation allowing the well operator to make more informed decisions in adjusting the rate at which the injection fluid is pumped into the rock formation. In operation 505, as the well operator adjusts the pumping of injection fluid into the rock formation, the well operator also can make adjustments the hydrocarbon production forecast. By more accurately managing the pumping of injection fluid and forecasting production of hydrocarbons from the rock formation, the well operator can more efficiently manage the production process. Considering the costs and complexity of drilling operations, the dual rate spontaneous imbibition model can significantly improve the production of hydrocarbons.

### General Information Regarding Computing Systems

As described in connection with the figures, the processing operations described in connection with the foregoing systems and methods can be performed by computing systems such as a personal computer, a desktop computer, a computer server, or cloud computing systems. As explained previously, certain operations of the foregoing methods can be performed by a combination of computing systems. The operations described herein can be embodied as instructions in computer-readable media that are executed by one of the foregoing computing systems.

The computing systems used in the foregoing embodiments can include typical components such as one or more processors, memories, input/output devices, and storage devices. The components of the computing systems can be interconnected, for example, by a system bus or by communication links. The components of the previously described computing systems are not exhaustive.

The one or more processors can be one or more hardware processors and can execute computer-readable instructions, such as instructions stored in a memory. The processor can be an integrated circuit, a central processing unit, a graphics processing unit, a multi-core processing chip, an SoC, a multi-chip module including multiple multi-core processing chips, or other hardware processor in one or more example embodiments. The hardware processor is known by other names, including but not limited to a computer processor, a microprocessor, and a multi-core processor.

The memory can store information including computer-readable instructions and data. The memory can be cache memory, a main memory, and/or any other suitable type of memory. The memory is a non-transitory computer-readable medium. In some cases, the memory can be a volatile memory device, while in other cases the memory can be a non-volatile memory device.

The storage device can be a non-transitory computer-readable medium that provides large capacity storage for a computing system. The storage device can be a disk drive, a flash drive, a solid-state device, or some other type of storage device. In some cases, the storage device can be a database that is remote from the computing system. The storage device can store operating system data, file data, database data, algorithms, and software modules, as examples.

### ASSUMPTIONS AND DEFINITIONS

For any figure shown and described herein, one or more of the components may be omitted, added, repeated, and/or substituted. Accordingly, embodiments shown in a particular figure should not be considered limited to the specific arrangements of components shown in such figure. Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure.

With respect to the example methods described herein, it should be understood that in alternate embodiments, certain operations of the methods may be performed in a different order, may be performed in parallel, or may be omitted. Moreover, in alternate embodiments additional steps may be added to the example methods described herein. Accordingly, the example methods provided herein should be viewed as illustrative and not limiting of the disclosure.

In the example embodiments described herein, numerous specific details are set forth in order to provide a more thorough understanding. However, it will be apparent to one of ordinary skill in the art that the embodiments may be practiced without these specific details. In other instances, well-known features have not been described in detail to avoid unnecessarily complicating the description.

The terms “a,” “an,” and “the” are intended to include plural alternatives, e.g., at least one. The terms “including”, “with”, and “having”, as used herein, are defined as comprising (i.e., open language), unless specified otherwise.

Values, ranges, or features may be expressed herein as “about”, from “about” one particular value, and/or to “about” another particular value. When such values, or ranges are expressed, other embodiments disclosed include the specific value recited, from the one particular value, and/or to the other particular value. Similarly, when values are expressed as approximations, by use of the antecedent “about,” it will be understood that the particular value forms another embodiment. It will be further understood that there are a number of values disclosed therein, and that each value is also herein disclosed as “about” that particular value in addition to the value itself. In another aspect, use of the term “about” means ±20% of the stated value, ±15% of the stated value, ±10% of the stated value, ±5% of the stated value, ±3% of the stated value, or ±1% of the stated value.

Although embodiments described herein are made with reference to example embodiments, it should be appreciated by those skilled in the art that various modifications are well within the scope of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A method for generating an imbibition model, the method comprising:
saturating a rock core sample from a rock formation with a liquid hydrocarbon to simulate a reservoir environment within the rock formation;
performing nuclear magnetic resonance (NMR) spectroscopy on the rock core sample saturated with the liquid hydrocarbon and obtaining a base line NMR measurement;
immersing the rock core sample in deuterated brine within a vessel;
applying a temperature and a pressure to the rock core sample within the vessel to simulate conditions of the reservoir environment;
obtaining multiple imbibed NMR measurements over a predetermined time by periodically removing the rock core sample from the vessel and performing the NMR spectroscopy on the rock core sample;
calculating inversions of the base line NMR measurement and the multiple imbibed NMR measurements to determine a porosity characteristic based upon a change in hydrocarbon saturation in the rock core sample during the predetermined time; and
fitting the porosity characteristic of the base line NMR measurements and the multiple imbibed NMR measurements to an imbibition model of hydrocarbon saturation for the rock core sample.

2. The method of claim 1, wherein the imbibition model comprises a first imbibition rate and a second imbibition rate.

3. The method of claim 2, wherein the first imbibition rate corresponds to a first type of pores in the rock core sample and the second imbibition rate corresponds to a second type of pores in the rock core sample that are larger than the first type of pores.

4. The method of claim 1, wherein the base line NMR measurement and the multiple imbibed NMR measurements comprise one of T2 measurements, T1-T2 measurements, and DT2 measurements.

5. The method of claim 1, wherein the NMR spectroscopy employs an echo train that produces a time-domain echo decay curve, wherein the echo train comprises a sequence of echo pulses spaced apart by an echo time.

6. The method of claim 5, wherein calculating inversions of the base line NMR measurement and the multiple imbibed NMR measurements comprises transforming the time-domain echo decay curves into at least one of a one-dimensional distribution and a two-dimensional distribution.

7. The method of claim 1, wherein the temperature is a selected temperature between 50 degrees F to 200 degrees F and the pressure is a selected pressure between 14 psi and 2000 psi.

8. A method for applying a dual rate imbibition model, the method comprising:
generating the dual rate imbibition model characterizing imbibition for a rock core sample, wherein the dual rate imbibition model is generated from multiple nuclear magnetic resonance (NMR) measurements of the rock core sample, wherein the dual rate imbibition model comprises a fast imbibition rate and a slow imbibition rate; and
adjusting, based on the fast imbibition rate and the slow imbibition rate, a rate at which a fluid is pumped during a time period into a rock formation represented by the rock core sample.

9. The method of claim 8, wherein the rate at which the fluid is pumped into the formation is greater during an earlier portion of the time period than during a later portion of the time period.

10. The method of claim 8, wherein the dual rate model corresponds to a type of rock of the formation.

11. The method of claim 8, wherein the first imbibition rate corresponds to a first type of pores in the rock core sample and the second imbibition rate corresponds to a second type of pores in the rock core sample that are larger than the first type of pores.

12. The method of claim 8, wherein generating the dual rate model further comprises:
saturating the rock core sample with a liquid hydrocarbon to simulate a reservoir environment within the rock formation;
performing NMR spectroscopy on the rock core sample saturated with the liquid hydrocarbon and obtaining a base line NMR measurement;
immersing the rock core sample in deuterated brine within a vessel;
applying a temperature and a pressure to the rock core sample within the vessel to simulate conditions of the reservoir environment;
obtaining multiple imbibed NMR measurements over a predetermined time by periodically removing the rock core sample from the vessel and performing the NMR spectroscopy on the rock core sample;
calculating inversions of the base line NMR measurement and the multiple imbibed NMR measurements to determine a porosity characteristic based upon a change in hydrocarbon saturation in the rock core sample during the predetermined time; and
fitting the porosity characteristic of the base line NMR measurements and the multiple imbibed NMR measurements to the dual rate imbibition model for the rock core sample.

13. The method of claim 12, wherein the base line NMR measurement and the multiple imbibed NMR measurements comprise one of T2 measurements, T1-T2 measurements, and DT2 measurements.

14. The method of claim 12, the NMR spectroscopy employs an echo train that produces a time-domain echo decay curve, wherein the echo train comprises a sequence of echo pulses spaced apart by an echo time.

15. The method of claim 14, wherein calculating inversions of the base line NMR measurement and the multiple imbibed NMR measurements comprises transforming the time-domain echo decay curves into at least one of a one-dimensional distribution and a two-dimensional distribution.

16. The method of claim 12, wherein the temperature is a selected temperature between 100 degrees F to 200 degrees F and the pressure is a selected pressure between 500 psi and 2000 psi.

17. A system comprising:
a vessel containing deuterated water, the vessel configured to immerse a rock core sample in the deuterated water and apply a temperature and a pressure to the rock core sample to simulate a reservoir environment;
a nuclear magnetic resonance (NMR) system, the NMR system configured to:
(i) obtain, by NMR spectroscopy, base line NMR measurements from the rock core sample when it is saturated with a hydrocarbon liquid and before it is immersed in the vessel; and
(ii) obtain multiple imbibed NMR measurements over a predetermined time by periodically removing the rock core sample from the vessel and performing NMR spectroscopy on the rock core sample; and
a computing system configured to:
(i) calculate inversions of the base line NMR measurements and the multiple imbibed NMR measurements to determine a porosity characteristic based upon a change in hydrocarbon saturation in the rock core sample during the predetermined time; and
(ii) fit the porosity characteristic of the base line NMR measurements and the multiple imbibed NMR measurements to an imbibition model of hydrocarbon saturation for the rock core sample.

18. The system of claim 17, wherein the model comprises a first imbibition rate and a second imbibition rate.

19. The system of claim 17, wherein the base line NMR measurement and the multiple imbibed NMR measurements comprise one of T2 measurements, T1-T2 measurements, and DT2 measurements.

20. The system of claim 17, wherein the NMR spectroscopy employs an echo train that produces a time-domain echo decay curve, wherein the echo train comprises a sequence of echo pulses spaced apart by an echo time.
